(19) United States
(12) Patent Application Publication
(10) Pub. No.: US 2008/0304247 A1
(43) Pub. Date: Dec. 11, 2008

(54) BOSS STRUCTURE AND CASING OF ELECTRONIC DEVICE USING THE SAME

(75) Inventors: YU-TUNG HSU, Taipei City (TW); CHONG-KUO LAI, Taipei City (TW)

Correspondence Address: J C PATENTS, INC., 4 VENTURE, SUITE 250, IRVINE, CA, 92618, US

(73) Assignee: COMPAL ELECTRONICS, INC., Taipei City (TW)

(21) Appl. No.: 12/035,920

(22) Filed: Feb. 22, 2008

(30) Foreign Application Priority Data
Jun. 5, 2007 (TW) 96120071

(51) Int. Cl. H05K 9/00; H05F 3/02; H05K 5/02

(52) U.S. Cl. 361/818; 361/220

(57) ABSTRACT

A boss structure including a boss and a metal layer is provided. The boss has a flat surface located on a top end of the boss and a chamfer connected to the flat surface. The metal layer wholly covers an exposed surface of the boss. Since the boss has the chamfer, a burr is located below the flat surface on the top end of the boss when the boss has the burr. Therefore, another element does not damage the burr of the boss when being locked to the boss structure, so as to keep the completeness of the metal layer of the boss structure.

### CROSS-REFERENCE TO RELATED APPLICATION

This application claims the priority benefit of Taiwan application serial no. 96120071, filed on Jun. 5, 2007. The entirety the above-mentioned patent application is hereby incorporated by reference herein and made a part of specification.

### BACKGROUND OF THE INVENTION

1. Field of the Invention

The present invention generally relates to a boss structure, in particular, to a boss structure covered by a metal layer, disposed on an inner surface of a casing of an electronic device, and capable of preventing electro-magnetic interference (EMI) and electro-static discharge (ESD).

2. Description of Related Art

In order to prevent EMI and ESD, usually a metal layer is coated on an inner surface of a plastic casing of an electronic device, and is electrically connected to a grounding point of the electronic device. For example, after the plastic casing is fabricated in an injection molding manner, a metal layer is coated on the inner surface of the plastic casing by sputtering process or evaporation process, and then the metal layer is electrically connected to the grounding point of a circuit board of the electronic device.

FIG. 1 is a schematic structural view of a conventional electronic device. Referring to FIG. 1, an electronic device 100 includes a casing 110, a circuit board 120, and a plurality of bolts 130. The circuit board 120 is locked to a plurality of bosses 140 formed on an inner surface of the casing 110 through the bolts 130. The casing 110 has a metal layer 112 wholly covering the inner surface of the casing 110 and exposed surface of the bosses 140. Therefore, when the circuit board 120 is locked to the bosses 140 through the bolts 130, the metal layer 112 can be electrically connected to the circuit board 120.

FIG. 2A is a schematic partial enlarged view of FIG. 1. Referring to FIGS. 1 and 2A, the plastic casing 110 was fabricated by injection molding, so after removing the mold, a burr 142 is formed on an outer edge of a top surface of the boss 140, which is also subsequently covered by the metal layer 112, as shown in FIG. 2A.

FIG. 2B is a schematic view showing that the burr in FIG. 2A is broken after being pressed. Referring to FIG. 2B, when the circuit board 120 is assembled to the bosses 140 of the casing 110 through the bolts 130, the burr 142 of FIG. 2A is pressed by the circuit board 120 and broke off the boss 140, as shown in FIG. 2B, and thus the completeness of the metal layer 112 is damaged.

### SUMMARY OF THE INVENTION

Accordingly, the present invention is directed to a boss structure adapted to be disposed on an inner surface of a casing of an electronic device, and a circuit board is able to be locked thereon through bolts.

The present invention is directed to a casing of an electronic device, and a circuit board is able to be locked on boss structures thereof through screws.

The present invention provides a boss structure, which includes a boss and a metal layer The boss has a flat surface located on a top end of the boss and a chamfer connected to the flat surface, and the metal layer wholly covers an exposed surface of the boss.

According to an embodiment of the present invention, the boss further has a hole and a female thread. One end of the hole is connected to the flat surface, and the female thread is formed on an inner surface of the hole.

According to an embodiment of the present invention, the chamfer is a bevel.

According to an embodiment of the present invention, the chamfer is a fillet.

According to an embodiment of the present invention, the boss has a burr formed between the chamfer and an outer surface of the boss and covered by the metal layer.

According to an embodiment of the present invention, the boss further has a shoulder away from the flat surface and connected to the flat surface through the chamfer.

According to an embodiment of the present invention, the boss has a burr formed between the shoulder and an outer surface of the boss and covered by the metal layer.

According to an embodiment of the present invention, the material of the boss is plastic.

The present invention further provides a casing of an electronic device, which includes a wall body, a boss, and a metal layer The boss is connected to the wall body and has a flat surface located on a top end of the boss and a chamfer connected to the flat surface, and the metal layer wholly covers an exposed surface of the boss.

According to an embodiment of the present invention, the boss further has a hole and a female thread. One end of the hole is connected to the flat surface, and the female thread is formed on an inner surface of the hole.

According to an embodiment of the present invention, the chamfer is a bevel.

According to an embodiment of the present invention, the chamfer is a fillet.

According to an embodiment of the present invention, the boss has a burr formed between the chamfer and an outer surface of the boss and covered by the metal layer.

According to an embodiment of the present invention, the boss further has a shoulder away from the flat surface and connected to the flat surface through the chamfer.

According to an embodiment of the present invention, the boss has a burr formed between the shoulder and an outer surface of the boss and covered by the metal layer.

According to an embodiment of the present invention, the boss is made of plastic.

In the present invention, a chamfer exists between the flat surface on the top end of the boss and the outer surface of the boss, so when a burr is formed on outer edge of the flat surface after injection molding fabrication, the burr is located below the flat surface. Therefore, the burr is not damaged when the circuit board is locked on the boss structure through the bolts and the completeness of the metal layer of the boss structure is kept.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic structural view of a conventional electronic device.

FIG. 2A is a schematic partial enlarged view of FIG. 1.

FIG. 2B is a schematic view showing that the burr in FIG. 2A is broken after being pressed.

FIG. 3 is a schematic structural view of a casing of an electronic device according to an embodiment of the present invention.

FIG. 4A is a schematic partial enlarged view of a boss structure in FIG. 3.

FIG. 4B is a schematic partial enlarged view of a boss structure according to a second embodiment of the present invention.

FIG. 4C is a schematic partial enlarged view of a boss structure according to a third embodiment of the present invention.

FIG. 4D is a schematic partial enlarged view of a boss structure according to a fourth embodiment of the present invention.

FIG. 4E is a schematic partial enlarged view of a boss structure according to a fifth embodiment of the present invention.

FIG. 4F is a schematic partial enlarged view of a boss structure according to a sixth embodiment of the present invention.

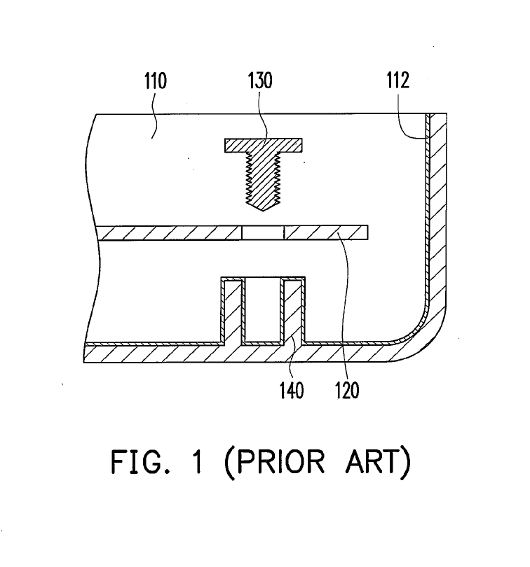

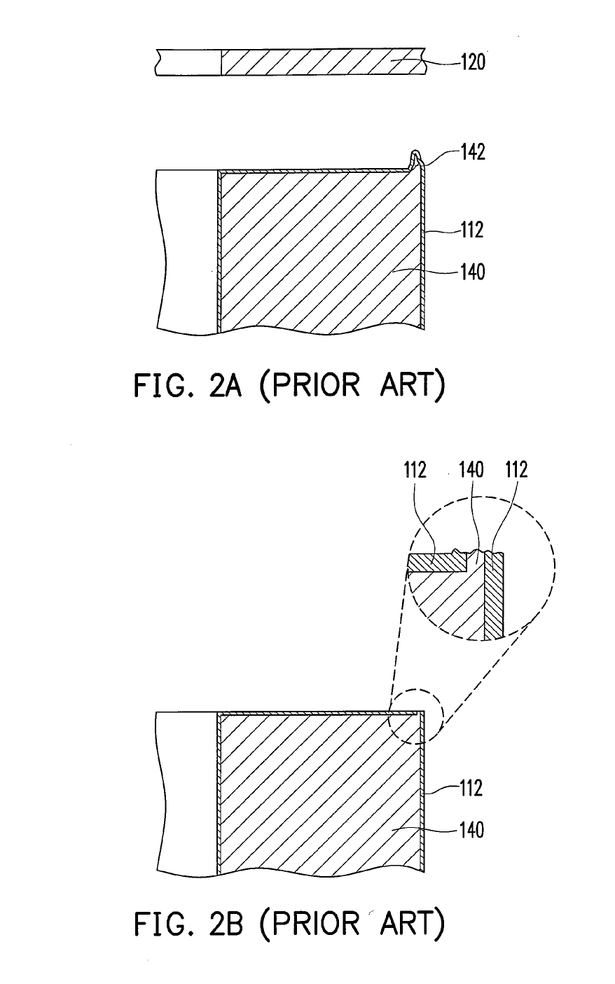

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts.

### First Embodiment

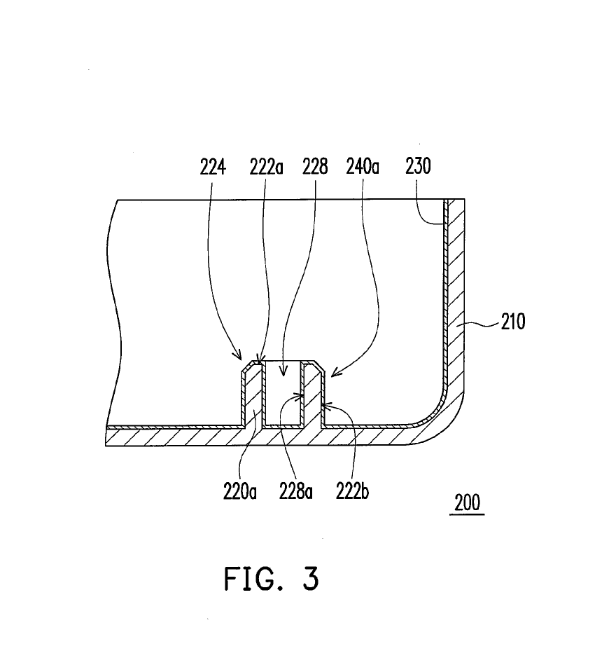

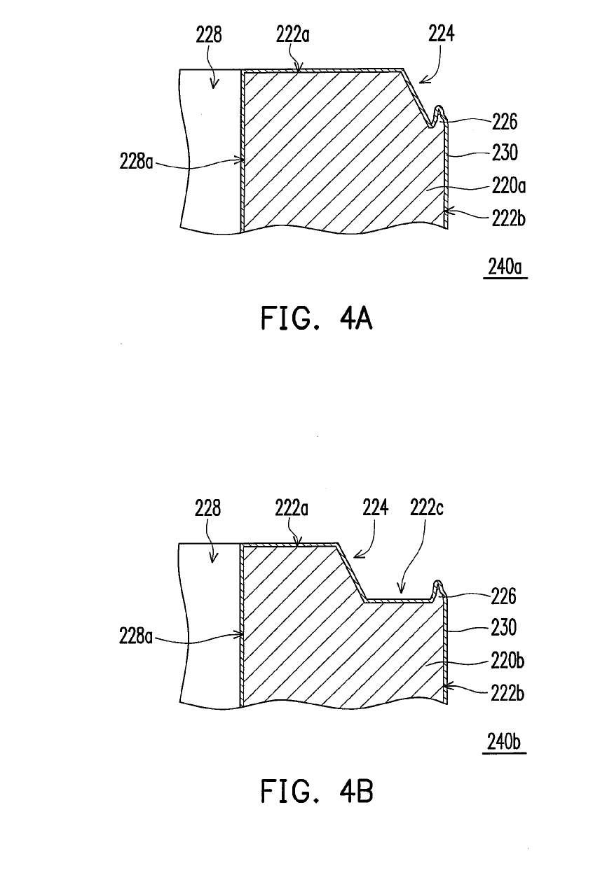

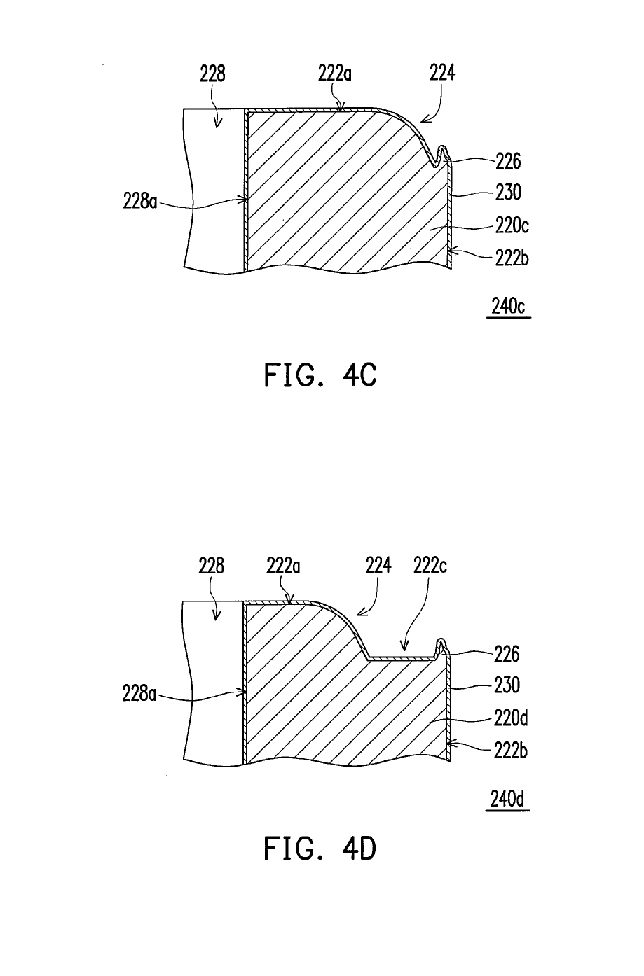

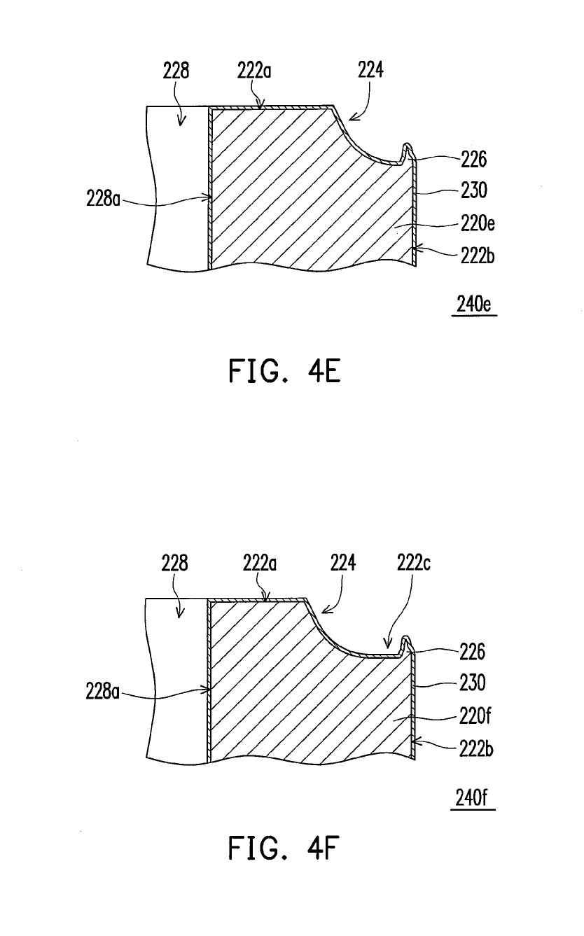

Referring to FIGS. 3 and 4A, FIG. 3 is a schematic structural view of a casing of an electronic device according to a first embodiment of the present invention, and FIG. 4A is a schematic partial enlarged view of a boss structure in FIG. 3. A casing 200 of the electronic device includes a wall body 210, a boss 220a, and a metal layer 230. The boss 220a is connected to an inner surface of the wall body 210, and has a flat surface 222a located on a top end of the boss 220a and a chamfer 224 connected to the flat surface 222a. The metal layer 230 wholly covers an exposed inner surface of the wall body 210 and an exposed surface of the boss 220a, and the boss 220a and the metal layer 230 covering the surface of the boss 220a form a boss structure 240a.

In the first embodiment, the chamfer 224 is for example a bevel, the materials of the wall body 210 and the boss 220a are, for example, plastic, and the wall body 210 and the boss 220a are fabricated in a manner of injection molding. Further, the boss 220a further has a burr 226 formed between the chamfer 224 and an outer surface 222b of the boss 220a, as shown in FIG. 4A, wherein the burr 226 is a remainder left on the boss 220a after the mold is removed. In addition, the metal layer 230 is, for example, formed on the exposed inner surface of the wall body 210 and the exposed surface of the boss 220a by sputtering process or evaporation process, and the like. The burr 226 is also covered by the metal layer 230.

In addition, the boss 220a can further have a hole 228 (as shown in FIG. 3) and a female thread (not shown). An end of the hole 228 is connected to the inner surface of the wall body 210, and the other end of the hole 228 is connected to the flat surface 222a of the top end of the boss 220a. The female thread is formed on an inner surface 228a of the hole 228, such that a circuit board or another electronic element can be locked on the boss 220a by using a bolt (not shown) to combine with the hole 228.

It should be noted that in the first embodiment, the boss 220a has the chamfer 224, such that a height of the burr 226 is below the flat surface 222a of the top end of the boss 220a. Therefore, when the circuit board (not shown) is assembled to the flat surface 222a of the boss 220a through the bolt, the burr 226 is not likely to be pressed. Therefore, the completeness of the metal layer 230 can be kept. However, the present invention is not limited to the embodiment. A plurality of embodiments on shape of the boss structure is illustrated herein below.

### Second Embodiment

Referring to FIG. 4B, a schematic partial enlarged view of the boss structure according to a second embodiment of the present invention is shown. A boss structure 240b in the second embodiment is similar to the boss structure 240a in the first embodiment, except that a boss 220b of the boss structure 240b further has a shoulder 222c away from the flat surface 222a and connected to the flat surface 222a through the chamfer 224. For this structural design, the burr 226 that forms on the boss 220b after the mold removal is located between the shoulder 222c and an outer surface 222b of the boss 220b, such that a height of the burr 226 is below the flat surface 222a of the top end of the boss 220b.

### Third Embodiment

Referring to FIG. 4C, a schematic partial enlarged view of the boss structure according to a third embodiment of the present invention is shown. A boss structure 240c in the third embodiment is similar to the boss structure 240a in the first embodiment, except that the chamfer 224 of the boss 220a in the first embodiment is a bevel, and the chamfer 224 of the boss 220c in the third embodiment is a fillet.

### Fourth Embodiment

Referring to FIG. 4D, a schematic partial enlarged view of the boss structure according to a fourth embodiment of the present invention is shown. A boss structure 240d in the fourth embodiment is similar to the boss structure 240b in the second embodiment, except that the chamfer 224 of the boss 220b in the second embodiment is a bevel, and the chamfer 224 of the boss 220d in the fourth embodiment is a fillet.

### Fifth Embodiment

Referring to FIG. 4E, a schematic partial enlarged view of the boss structure according to a fifth embodiment of the present invention is shown. A boss structure 240e in the fifth embodiment is similar to the boss structure 240c in the third embodiment, except that the chamfer 224 of the boss 220c in the third embodiment is a protruding fillet, and the chamfer 224 of the boss 220e in the fifth embodiment is a recessed fillet.

### Sixth Embodiment

Referring to FIG. 4F, a schematic partial enlarged view of the boss structure according to a sixth embodiment of the present invention is shown. A boss structure 240f in the sixth embodiment is similar to the boss structure 240d in the fourth embodiment, except that the chamfer 224 of the boss 220d in the fourth embodiment is a protruding fillet, and the chamfer 224 of the boss 220f in the sixth embodiment is a recessed fillet.

To sum up, in the present invention, the chamfer exists between the flat surface on the top end of the boss and the outer surface of the boss, so when the burr is formed on the outer edge of the boss, the burr is located below the flat surface. Therefore, the burr is not damaged when the circuit board or another electronic element is locked on the boss structure and the completeness of the metal layer of the boss structure is kept.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A boss structure, comprising:
a boss, having a flat surface located on a top end of the boss and a chamfer connected to the flat surface; and
a metal layer, wholly covering an exposed surface of the boss.

2. The boss structure according to claim 1, wherein the boss further comprises a hole and a female thread, one end of the hole is connected to the flat surface, and the female thread is formed on an inner surface of the hole.

3. The boss structure according to claim 1, wherein the chamfer is a bevel.

4. The boss structure according to claim 1, wherein the chamfer is a fillet.

5. The boss structure according to claim 1, wherein the boss further comprises a burr formed between the chamfer and an outer surface of the boss and covered by the metal layer.

6. The boss structure according to claim 1, wherein the boss further comprises a shoulder away from the flat surface and connected to the flat surface through the chamfer.

7. The boss structure according to claim 6, wherein the boss further comprises a burr formed between the shoulder and an outer surface of the boss and covered by the metal layer.

8. The boss structure according to claim 1, wherein a material of the boss is plastic.

9. A casing of an electronic device, comprising:
a wall body;
a boss, connected to the wall body, and comprising a flat surface located on a top end of the boss and a chamfer connected to the flat surface; and
a metal layer, wholly covering an exposed surface of the boss.

10. The casing of an electronic device according to claim 9, wherein the boss further comprises a hole and a female thread, one end of the hole is connected to the flat surface, and the female thread is formed on an inner surface of the hole.

11. The casing of an electronic device according to claim 9, wherein the chamfer is a bevel.

12. The casing of an electronic device according to claim 9, wherein the chamfer is a fillet.

13. The casing of an electronic device according to claim 9, wherein the boss further comprises a burr formed between the chamfer and an outer surface of the boss and covered by the metal layer.

14. The casing of an electronic device according to claim 9, wherein the boss further comprises a shoulder away from the flat surface and connected to the flat surface through the chamfer.

15. The casing of an electronic device according to claim 14, wherein the boss further comprises a burr formed between the shoulder and an outer surface of the boss and covered by the metal layer.

16. The casing of an electronic device according to claim 9, wherein a material of the boss is plastic.
